(19) United States
(12) Patent Application Publication
(10) Pub. No.: US 2023/0172072 A1
(43) Pub. Date: Jun. 1, 2023

(54) LAYOUT AND PROCESSING METHOD THEREOF, STORAGE MEDIUM, AND PROGRAM PRODUCT

(71) Applicants: CHANGXIN MEMORY TECHNOLOGIES, INC., Hefei (CN); Beijing Superstring Academy of Memory Technology, Beijing (CN)

(72) Inventors: Xiaoguang WANG, Hefei (CN); Huihui LI, Hefei (CN); Wei CHANG, Hefei (CN); Kanyu CAO, Hefei (CN)

(21) Appl. No.: 17/827,778

(22) Filed: May 29, 2022

Related U.S. Application Data
(63) Continuation of application No. PCT/CN2022/078088, filed on Feb. 25, 2022.

(30) Foreign Application Priority Data
Nov. 30, 2021 (CN) 202111444495.3

(51) Int. Cl. H01L 43/08; H01L 27/22; H01L 43/02; H01L 43/12

(52) U.S. Cl. CPC H01L 43/08; H01L 27/226; H01L 43/02; H01L 43/12

(57) ABSTRACT

Embodiments provide a layout and a processing method thereof, a storage medium and a program product. The layout has a first memory area and a second memory area. The layout includes a base substrate array pattern and a storage pattern, the base substrate array pattern includes a plurality of plug patterns spaced apart; and the storage pattern includes a magnetic tunnel junction pattern in the first memory area and a capacitor pattern in the second memory area. The magnetic tunnel junction pattern shares a partially overlapped area with a given one of the plurality of plug patterns in the first memory area, and the capacitor pattern shares a partially overlapped area with a given one of the plurality of plug patterns in the second memory area.

### CROSS-REFERENCE TO RELATED APPLICATION

This application is a continuation of PCT/CN2022/078088, filed on Feb. 25, 2022, which claims priority to Chinese Patent Application No. 202111444495.3 titled “LAYOUT AND PROCESSING METHOD THEREOF, STORAGE MEDIUM, AND PROGRAM PRODUCT” and filed to the State Patent Intellectual Property Office on Nov. 30, 2021, the entire contents of which are incorporated herein by reference.

### TECHNICAL FIELD

The present disclosure relates to the field of semiconductor technology, and more particularly, to a layout and a processing method thereof, a storage medium, and a program product.

### BACKGROUND

With the development of semiconductor technologies, integration of semiconductor devices has been continuously improved, and sizes of the semiconductor devices are becoming smaller and smaller. Sizes of memories especially magnetic random access memories (MRAM) need to be further miniaturized to improve the integration of the MRAM. To further improve the integration of the semiconductor devices, layouts of the semiconductor devices need to be further optimized.

### SUMMARY

In view of the above problems, embodiments of the present disclosure provide a layout and a processing method thereof, a storage medium and a program product, to improve integration of a semiconductor device.

A first aspect of the embodiments of the present disclosure provides a layout having a first memory area and a second memory area at least partially surrounding the first memory area. The layout includes: a base substrate array pattern including a plurality of plug patterns spaced apart; and a storage pattern including a magnetic tunnel junction pattern positioned in the first memory area and a capacitor pattern positioned in the second memory area. The magnetic tunnel junction pattern shares a partially overlapped area with a given one of the plurality of plug patterns positioned in the first memory area, and the capacitor pattern shares a partially overlapped area with a given one of the plurality of plug patterns positioned in the second memory area.

A second aspect of the embodiments of the present disclosure provides a method for processing a layout, where the layout has a first memory area and a second memory area at least partially surrounding the first memory area. The processing method includes: forming, in a blank layout, a base substrate array pattern including a plurality of plug patterns spaced apart; and forming a storage pattern, which includes a magnetic tunnel junction pattern positioned in the first memory area and a capacitor pattern positioned in the second memory area. The magnetic tunnel junction pattern shares a partially overlapped area with a given one of the plurality of plug patterns positioned in the first memory area, and the capacitor pattern shares a partially overlapped area with a given one of the plurality of plug patterns positioned in the second memory area.

A third aspect of the embodiments of the present disclosure provides a storage medium storing computer-executable instructions, where the computer-executable instructions are executable by a processor, whereby the processing method is implemented. The storage medium in the embodiments of the present disclosure is configured to implement the above processing method, and thus at least has the advantages of the above processing method. Reference may be made to the above for concrete effects of the storage medium, and detailed descriptions thereof are omitted here.

A fourth aspect of the embodiments of the present disclosure provides a program product including a computer program, where the computer program is executable by a processor, whereby the processing method is implemented. The program product in the embodiments of the present disclosure is configured to implement the above processing method, and thus at least has the advantages of the above processing method. Reference may be made to the above for concrete effects of the program product, and detailed descriptions thereof are omitted here.

### BRIEF DESCRIPTION OF THE DRAWINGS

FIG. 1 is a schematic diagram showing a core area and a peripheral area of a layout according to an embodiment of the present disclosure;

FIG. 2 is a schematic diagram showing a magnetic tunnel junction pattern according to an embodiment of the present disclosure;

FIG. 3 is a schematic diagram showing a capacitor pattern according to an embodiment of the present disclosure;

FIG. 4 is a schematic diagram showing an active area sub pattern in a first memory area according to an embodiment of the present disclosure;

FIG. 5 is a schematic diagram showing an active area sub pattern in a second memory area according to an embodiment of the present disclosure;

FIG. 6 is a schematic diagram showing a word line pattern in the first memory area according to an embodiment of the present disclosure;

FIG. 7 is a schematic diagram showing a word line pattern in the second memory area according to an embodiment of the present disclosure;

FIG. 8 is a schematic diagram showing a conductive pillar sub pattern in the first memory area according to an embodiment of the present disclosure;

FIG. 9 is a schematic diagram showing a conductive pillar sub pattern in the second memory area according to an embodiment of the present disclosure;

FIG. 10 is a schematic diagram showing a conductive line pattern in the first memory area according to an embodiment of the present disclosure;

FIG. 11 is a schematic diagram showing a conductive line pattern in the second memory area according to an embodiment of the present disclosure;

FIG. 12 is a schematic diagram showing a first plug sub pattern in the first memory area according to an embodiment of the present disclosure;

FIG. 13 is a schematic diagram showing a first plug sub pattern in the second memory area according to an embodiment of the present disclosure;

FIG. 14 is a schematic diagram showing a second plug sub pattern in the first memory area according to an embodiment of the present disclosure;

FIG. 15 is a schematic diagram showing a second plug sub pattern in the second memory area according to an embodiment of the present disclosure;

FIG. 16 is a schematic diagram showing a conductive pattern in the second memory area according to an embodiment of the present disclosure;

FIG. 17 is a schematic diagram showing a second electrode contact pattern in the first memory area according to an embodiment of the present disclosure;

FIG. 18 is a schematic diagram showing a second data line pattern in the first memory area according to an embodiment of the present disclosure; and

FIG. 19 is a flowchart of a method for processing a layout according to an embodiment of the present disclosure.

### DETAILED DESCRIPTION

To improve integration of a semiconductor device, the layout in the embodiments of the present disclosure includes a base substrate array pattern and a storage patter. The base substrate array pattern includes a plurality of plug patterns spaced apart, and the storage pattern includes a magnetic tunnel junction pattern positioned in a first memory area and a capacitor pattern positioned in a second memory area. The magnetic tunnel junction pattern shares a partially overlapped area with a given one of the plurality of plug patterns positioned in the first memory area, and the capacitor pattern shares a partially overlapped area with a given one of the plurality of plug patterns positioned in the second memory area. The base substrate array pattern, the magnetic tunnel junction pattern and the capacitor pattern are formed in the layout. Therefore, when the layout is configured for production subsequently, a magnetic random access memory (MRAM) may be fabricated by means of a fabrication process of a dynamic random access memory (DRAM), such that a memory density of the MRAM is improved, and thus the integration of the MRAM is further improved, and the integration of the semiconductor device is improved.

To make the above objectives, features, and advantages of the embodiments of the present disclosure more apparent and lucid, the technical solutions in the embodiments of the present disclosure will be described clearly and completely below with reference to the accompanying drawings in the embodiments of the present disclosure. Apparently, the described embodiments are merely some but not all of the embodiments of the present disclosure. All other embodiments obtained by a person of ordinary skill in the art based on the embodiments of the present disclosure without creative efforts shall fall within the protection scope of the present disclosure.

Referring to FIG. 1, the layout has a first memory area 11 and a second memory area 12, and different storage patterns are formed in the first memory area 11 and the second memory area 12. For example, patterns of the MRAM are formed in the first memory area 11, and patterns of the DRAM are formed in the second memory area 12. As shown in FIG. 1, the first memory area 11 and the second memory area 12 form a core area 10, which may also be referred as an array area. The core area 10 is configured to form a memory cell of the memory. The layout also includes a peripheral area 20 surrounding the core area 10 in a circle, and the peripheral area 20 is configured to form a control circuit of the memory.

The second memory area 12 at least partially surrounds the first memory area 11. For example, the second memory area 12 completely surrounds the first memory area 11, or the second memory area 12 partially surrounds the first memory area 11. In some embodiments, one edge of the first memory area 11 is partially overlapped with one edge of the second memory area 12. As shown in FIG. 1, a left edge of the first memory area 11 is partially overlapped with a left edge of the second memory area 12. In this way, the first memory area 11 may be adjacent to the peripheral area 20, such that the patterns in the first memory area 11 can be connected to the peripheral area 20. In addition, the other three edges of the first memory area 11 are adjacent to the second memory area 12, such that an insulation pattern can be arranged between the first memory area 11 and the second memory area 12.

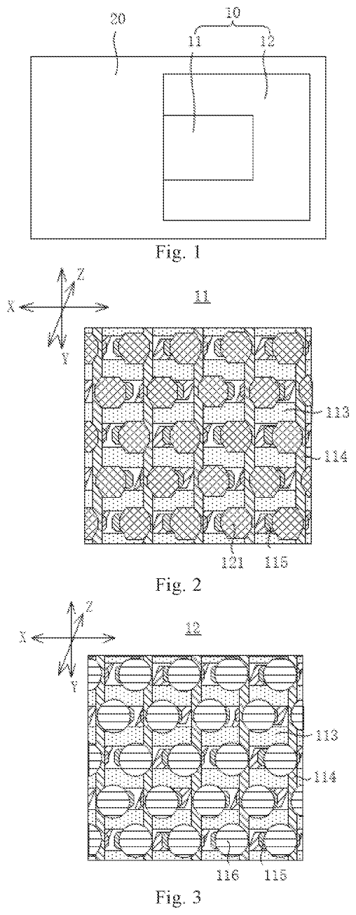

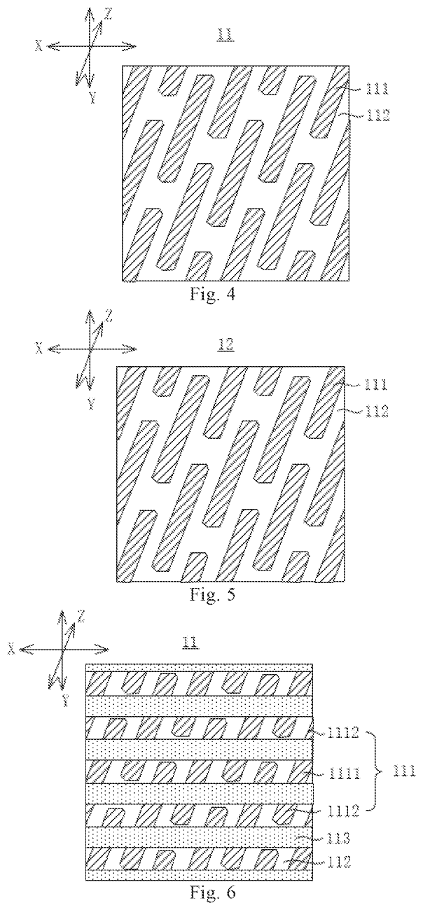

Referring to FIG. 2 and FIG. 3, the layout includes a base substrate array pattern and a storage pattern, where the base substrate array pattern includes a plurality of plug patterns 115 spaced apart, and each of the plurality of plug patterns 115 shares a partially overlapped area with the storage pattern, such that each of the plurality of plug patterns 115 is connected to the storage pattern.

In some embodiments, as shown in FIG. 2 and FIG. 3, the storage pattern includes a capacitor pattern 116 and a magnetic tunnel junction (MTJ) pattern 121, where the MTJ pattern 121 is positioned in the first memory area 11, and the MTJ pattern 121 shares a partially overlapped area with each of the plurality of plug patterns 115 positioned in the first memory area 11. The capacitor pattern 116 is positioned in the second memory area 12, and the capacitor pattern 116 shares a partially overlapped area with each of the plurality of plug patterns 115 positioned in the second memory area 12.

In a possible example, referring to FIGS. 4 to 15, the base substrate array pattern includes a substrate pattern, a plurality of first data line patterns 114, and a plurality of plug patterns 115. The substrate pattern, the plurality of first data line patterns 114 and the plurality of plug patterns 115 are respectively positioned in different pattern layers of the layout, subsequently are transferred to different photomasks to form photomask patterns, and are respectively used in different patterning steps for fabricating the semiconductor devices to form the desired semiconductor devices on a semiconductor substrate.

Referring to FIG. 4 and FIG. 5, the substrate pattern includes a plurality of active area sub patterns 111 spaced apart, which are configured to define positions of active areas in the semiconductor substrate. The plurality of active area sub patterns 111 extend along a first direction (Z direction as shown in FIG. 4 and FIG. 5) and are arranged in parallel. Adjacent two of the plurality of active area sub patterns 111 are staggered in a second direction (Y direction as shown in FIG. 4 and FIG. 5), where the second direction intersects with the first direction. That is, there is an angle between the second direction and the first direction. Between the plurality of active area sub patterns 111 there is provided an isolation sub pattern 112, which is configured to define a position of a shallow trench isolation (STI) in the semiconductor substrate. The plurality of active area sub patterns 111 and the isolation sub pattern 112 are transferred together onto the same photomask.

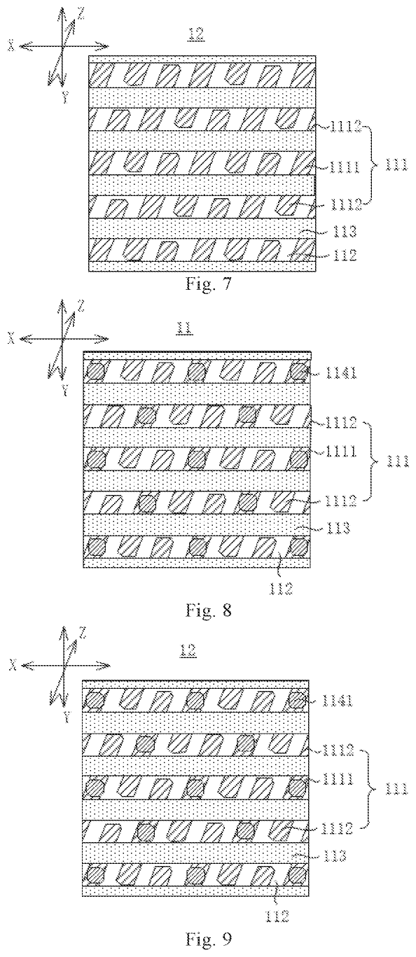

Referring to FIG. 6 and FIG. 7, the substrate pattern is also provided with a plurality of word line patterns 113 spaced apart. The plurality of word line patterns 113 and the plurality of active area sub patterns 111 are positioned in different pattern layers of the layout. Each of the plurality of word line patterns 113 is configured to define a position of a word line in the semiconductor substrate, where the word line may be a buried word line. The plurality of word line patterns 113 extend in a third direction (X direction as shown in FIG. 6) and are arranged in parallel in the second direction (the Y direction as shown in FIG. 6). The third direction intersects with the first direction, and the third direction also intersects with the second direction. Exemplarily, the second direction may be perpendicular to the third direction, and there is an intersection angle between the first direction and the second direction and between the first direction and the third direction.

As shown in FIG. 6 and FIG. 7, each of the plurality of word line patterns 113 intersects with some of the plurality of active area sub patterns 111 positioned in the same row and passes through these active area sub patterns 111, and each of the plurality of word line patterns 113 divides these active area sub patterns 111 into different areas. When the plurality of active area sub patterns 111 and the plurality of word line patterns 113 are transferred onto the semiconductor substrate to form active areas and word lines, different areas of the active areas are electrically connected to different structures. For example, the active areas are divided by the word lines into areas electrically connected to bit lines (BL) and areas electrically connected to capacitors. A layer in the word lines in contact with the active areas is a dielectric layer, which may be used as a gate oxide layer to ensure insulation between the word lines and the active areas.

In some possible embodiments, number of word line patterns 113 intersecting with some of the plurality of active area sub patterns 111 in the same row is two, and the two word line patterns 113 separate these active area sub patterns 111 intersecting therewith into a first contact area 1111 positioned in middle and second contact areas 1112 positioned on two sides of the first contact area 1111. As shown in FIG. 6 and FIG. 7, each of the plurality of active area sub patterns 111 is divided by the two word line patterns 113 into a first contact area 1111 and second contact areas 1112 positioned on two sides of the first contact area 1111, where a shape of the first contact area 1111 may be a parallelogram.

It should be noted that part of the plurality of word line patterns 113 may pass through the first memory area 11 and the second memory areas 12 simultaneously, and another part of the plurality of word line patterns 113 may only pass through the second memory areas 12. Number of the plurality of word line patterns 113 passing through the first memory area 11 and the second memory areas 12 simultaneously is at least one. In the one word line pattern 113, a second insulation pattern is also provided between part of the one word line pattern 113 positioned in the first memory area 11 and part of the one word line pattern 113 positioned in the second memory area 12.

In some embodiments, each of the plurality of word line patterns 113 in the second memory areas 12 corresponds to one of the plurality of word line patterns 113 in the first memory area 11, each of the plurality of word line patterns 113 in the second memory areas 12 and the one of the plurality of word line patterns 113 in the first memory area 11 are positioned on a same straight line along the third direction, and between each of the plurality of word line patterns 113 in the second memory areas 12 and the one of the plurality of word line patterns 113 in the first memory area 11 there are provided insulation patterns.

In this way, when each of the plurality of word line patterns 113 is transferred onto the semiconductor substrate to form word lines, insulation is provided between the word lines in the first memory area 11 and the word lines in the second memory areas 12, and the first memory area 11 and the second memory areas 12 may be electrically connected to different control circuits, such that the DRAM and the MRAM can be driven separately, which improves flexibility in control of the semiconductor device. In addition, each of the word lines positioned in the first memory area 11 and one word line positioned in the second memory area 12 are positioned on the same straight line, which facilitates the fabrication of the word lines.

Referring to FIGS. 8 to 11, there are a plurality of first data line patterns 114, and the plurality of first data line patterns 114 are spaced apart and extend along the second direction (the Y direction as shown in FIG. 10), where the second direction intersects with the first direction. Each of the plurality of first data line patterns 114 shares a partially overlapped area with some of the plurality of active area sub patterns 111 positioned in the same column.

As shown in FIG. 8 to FIG. 11, each of the plurality of first data line patterns 114 includes a plurality of conductive pillar sub patterns 1141 spaced apart and a plurality of conductive line sub patterns 1142 extending along the second direction, where the plurality of conductive pillar sub patterns 1141 and the plurality of conductive line sub patterns 1142 are positioned in different pattern layers of the layout.

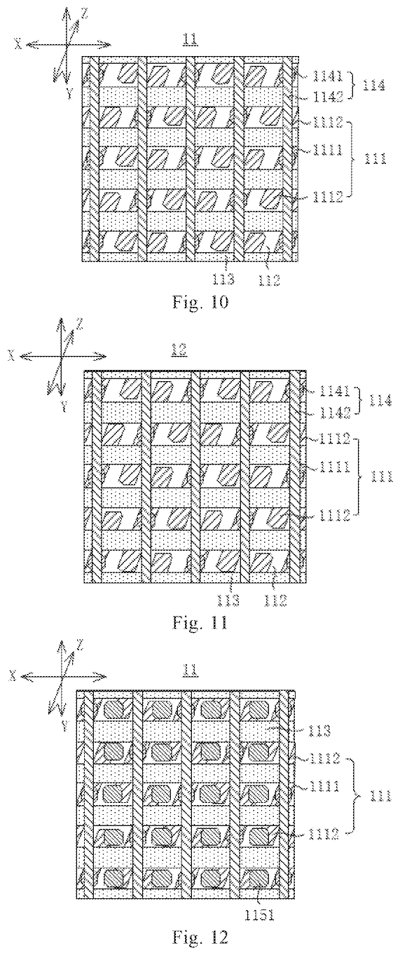

Referring to FIG. 8 and FIG. 9, part of each of the plurality of conductive pillar sub patterns 1141 positioned in the first memory area 11 is configured to define a position of a source line contact on the semiconductor substrate. Part of each of the plurality of conductive pillar sub patterns 1141 positioned in the second memory area 12 is configured to define a position of a bit line contact on the semiconductor substrate. Referring to FIG. 10 and FIG. 11, part of each of the plurality of conductive line sub patterns 1142 positioned in the first memory area 11 is configured to form a source line pattern, which is configured to define a position of a source line on the semiconductor substrate. Part of each of the plurality of conductive line sub patterns 1142 positioned in the second memory area 12 is configured to form a bit line pattern, which is configured to define a position of a bit line on the semiconductor substrate.

With continued reference to FIGS. 8 to 11, each of the plurality of conductive pillar sub patterns 1141 shares a partially overlapped area with one of the plurality of active area sub patterns 111, and each of the plurality of conductive line sub patterns 1142 passes through some of the plurality of conductive pillar sub patterns 1141 positioned in the same column. In some embodiments, each of the plurality of conductive pillar sub patterns 1141 is overlapped with a partial area of the first contact area 1111 of each of the plurality of active area sub patterns 111. As shown in FIG. 8 and FIG. 9, each of the plurality of conductive pillar sub patterns 1141 shares a partially overlapped area with a middle area (the first contact area 1111) of each of the plurality of active area sub patterns 111. Two adjacent columns of conductive pillar sub patterns 1141 are staggered along the second direction.

Referring to FIGS. 12 to 15, each of the plurality of plug patterns 115 is positioned between adjacent two of the plurality of first data line patterns 114 and shares a partially overlapped area with each of the plurality of active area sub patterns 111. In some embodiments, each of the plurality of plug patterns 115 is overlapped with a partial area of the second contact area 1112. That is, each of the plurality of plug patterns 115 shares a partially overlapped area with an edge area of each of the plurality of active area sub patterns 111.

In a possible example, as shown in FIGS. 12 to 15, the plurality of plug patterns 115 includes first plug sub patterns 1151 and second plug sub patterns 1152, where the first plug sub patterns 1151 and the second plug sub patterns 1152 are positioned on different pattern layers in the layout. There are a plurality of first plug sub patterns 1151, and the plurality of first plug sub patterns 1151 are spaced apart. There are a plurality of second plug sub patterns 1152, and the plurality of second plug sub patterns 1152 are spaced apart. The plurality of second plug sub patterns 1152 are in one-to-one correspondence with the plurality of first plug sub patterns 1151. That is, one of the plurality of first plug sub patterns 1151 corresponds to one of the plurality of second plug sub patterns 1152. Each of the plurality of first plug sub patterns 1151 and each of the plurality of second plug sub pattern 1152 corresponding to each other share a partially overlapped area.

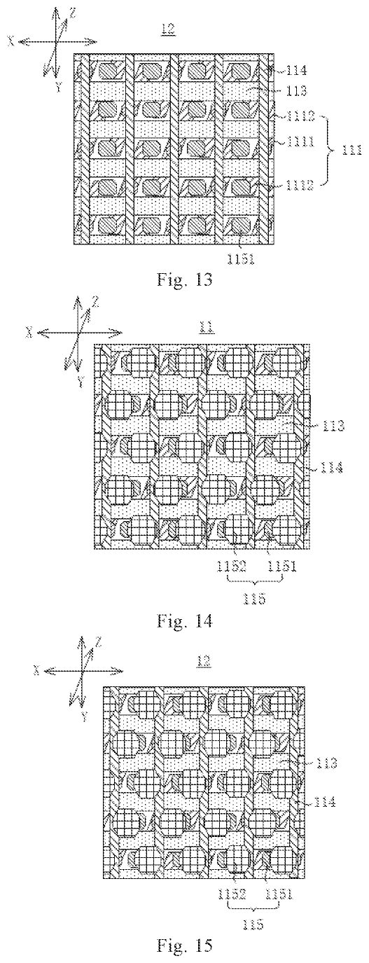

Each of the plurality of first plug sub patterns 1151 is positioned between adjacent two of the plurality of first data line patterns 114. As shown in FIG. 12 and FIG. 13, each of the plurality of first plug sub patterns 1151 is also positioned between adjacent two of the plurality of word line patterns 113. Each of the plurality of first plug sub patterns 1151 positioned in the first memory area 11 is configured to define a position of a first electrode contact, and each of the plurality of first plug sub patterns 1151 positioned in the second memory area 12 is configured to define a position of a node contact. As shown in FIG. 12 and FIG. 13, the plurality of first plug sub patterns 1151 may be arranged in a matrix array. That is, every four of the plurality of first plug sub patterns 1151 constitute a group, and a group of first plug sub patterns 1151 encircle into a virtual rectangle, where each first plug sub pattern 1151 in a group of first plug sub patterns 1151 is positioned on one vertex of the virtual rectangle, respectively.

Referring to FIG. 14 and FIG. 15, each of the plurality of second plug sub patterns 1152 shares a partially overlapped area with each of the plurality of first data line patterns 114 and each of the plurality of first plug sub patterns 1151, respectively. Each of the plurality of second plug sub patterns 1152 may also share a partially overlapped area with adjacent two of the plurality of word line patterns 113. For example, as shown in FIG. 14 and FIG. 15, an upper area of each of the plurality of second plug sub patterns 1152 is partially overlapped with one of the plurality of word line patterns 113, and a lower area of each of the plurality of second plug sub patterns 1152 is partially overlapped with another one of the plurality of word line patterns 113, and the two word line patterns 113 are adjacent to each other.

The plurality of second plug patterns 115 may be arranged in a hexagonal close-packed structure. That is, every six of the plurality of second plug sub patterns 1152 constitute a group, and a group of second plug sub patterns 1152 encircle into a virtual regular hexagon, where each second plug sub pattern 1152 in a group of second plug sub patterns 1152 is respectively positioned on one vertex of the virtual regular hexagon, to improve an arrangement density of the plurality of second plug sub patterns 1152.

Each of plurality of second plug sub patterns 1152 positioned in the first memory area 11 forms a first electrode contact pattern configured to define a position of the first electrode contact, which may be a bottom electrode contact. Each of plurality of second plug sub patterns 1152 positioned in the second memory area 12 forms a landing pad pattern, which is configured to define a position of a landing pad.

Referring to FIG. 14, FIG. 15, FIG. 2 and FIG. 3, the magnetic tunnel junction pattern 121 is positioned in the first memory area 11 and is configured to define a position of the magnetic tunnel junction. There are a plurality of magnetic tunnel junction patterns 121 positioned in the first memory area 11, and the plurality of magnetic tunnel junction patterns 121 are spaced apart. The plurality of magnetic tunnel junction patterns 121 may be arranged in a hexagonal close-packed structure, and each of the plurality of magnetic tunnel junction patterns 121 shares a partially overlapped area with one of the first electrode contact patterns.

The capacitor patterns 116 are positioned in the second memory area 12 and are configured to define positions of capacitors. There are a plurality of capacitor patterns 116 positioned in the second memory area 12, and the plurality of capacitor patterns 116 are spaced apart. The plurality of capacitor patterns 116 are arranged in a hexagonal close-packed structure, and each of the plurality of capacitor patterns 116 shares a partially overlapped area with one landing pad pattern.

Referring to FIG. 3 and FIG. 16, the layout further includes a conductive pattern 117 positioned in the second memory area 12, where the conductive pattern 117 covers each of the plurality of capacitor patterns 116. The conductive pattern 117 may fill up the second memory area 12, and the conductive pattern 117 is configured to define a position of the conductive layer, which may be a whole-layer structure wrapping the capacitor to electrically connect the capacitor to a control circuit.

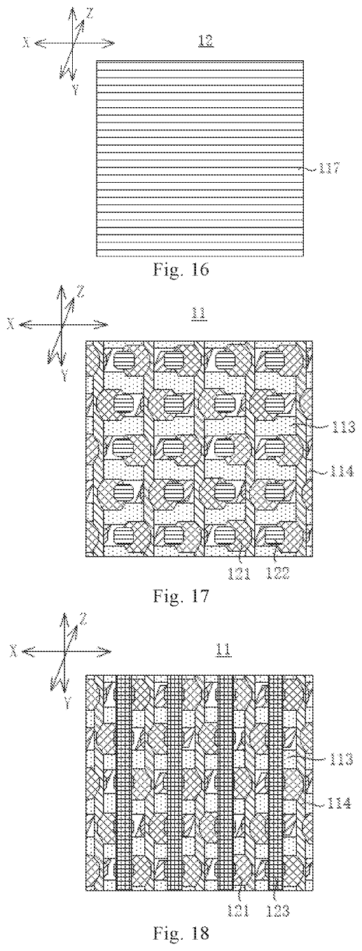

Referring to FIG. 2 and FIG. 17, the layout further includes a plurality of second electrode contact patterns 122, and each of the plurality of second electrode contact patterns 122 is overlapped with at least a partial area of one of the plurality of magnetic tunnel junction patterns 121. Each of the plurality of second electrode contact patterns 122 is configured to define a position of a second electrode contact, which may be a top electrode contact.

As shown in FIG. 17, the plurality of magnetic tunnel junction patterns 121 are arranged in a hexagonal close-packed structure, the plurality of second electrode contact patterns 122 are arranged in a rectangular array, magnetic tunnel junction patterns 121 and second electrode contact patterns 122 positioned in the same row have the same overlapped position, and magnetic tunnel junction patterns 121 and second electrode contact patterns 122 positioned in adjacent two rows have different overlapped position. In this way, the plurality of second electrode contact patterns 122 arranged in the rectangular array may be formed on the plurality of magnetic tunnel junction patterns 121 arranged in the hexagonal close-packed structure, such that a second data line pattern 123 (referring to FIG. 18) passing through the second electrode contact patterns 122 in the same column may be a straight line.

As shown in FIG. 18, the layout further includes a plurality of second data line patterns 123 spaced apart and extending along the second direction, where each of the plurality of second data line patterns 123 shares a partially overlapped area with each of the plurality of second electrode contact pattern 122 and passes through some of the plurality of second electrode contact patterns 122 positioned in the same column. As shown in FIG. 18, the plurality of second data line patterns 123 and the plurality of first data line patterns 114 are alternately arranged in the third direction.

To sum up, the layout in the embodiments of the present disclosure has a first memory area 11 and a second memory area 12 at least partially surrounding the first memory area 11. The layout also includes a base substrate array pattern and a storage pattern, where the base substrate array pattern includes a plurality of plug patterns 115 spaced apart, and the storage pattern includes a plurality of magnetic tunnel junction patterns 121 positioned in the first memory area 11 and a plurality of capacitor patterns 116 positioned in the second memory area 12. Each of the plurality of magnetic tunnel junction patterns 121 shares a partially overlapped area with a given one of the plurality of plug patterns 115 positioned in the first memory area 11, and each of the plurality of capacitor patterns 116 shares a partially overlapped area with a given one of the plurality of plug patterns 115 positioned in the second memory area 12. Each of the plurality of magnetic tunnel junction patterns 121 positioned in the first memory area 11 and the base substrate array pattern may be configured to form patterns of an MRAM, and each of the plurality of capacitor patterns 116 positioned in the second memory area 12 and the base substrate array pattern may be configured to form patterns of a DRAM, such that the layout includes both the patterns of the DRAM and the patterns of the MRAM. That is, the patterns of the DRAM and the patterns of the MRAM are integrated into one layout. When the layout is configured for production subsequently, the MRAM may be fabricated by means of a fabrication process of the DRAM, such that a memory density of the MRAM is improved, and thus the integration of the MRAM is further improved, and the integration of the semiconductor device is improved.

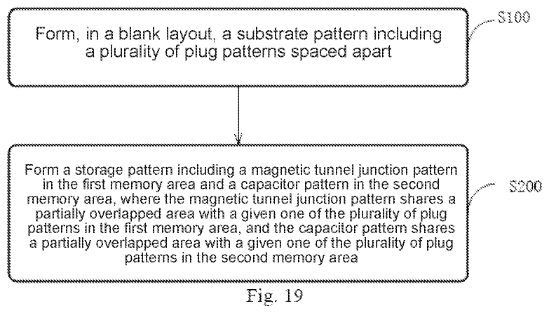

The embodiments of the present disclosure further provide a method for processing a layout. As shown in FIG. 1, the layout has a first memory area 11 and a second memory area 12 at least partially surrounding the first memory area 11. Different storage patterns are formed in the first memory area 11 and the second memory area 12. For example, the patterns of the MRAM are formed in the first memory area 11, and the patterns of the DRAM are formed in the second memory area 12. Referring to FIG. 19, the method for processing a layout includes following steps.

Step S100: forming, in a blank layout, a substrate pattern including a plurality of plug patterns spaced apart.

Referring to FIG. 2 and FIG. 3, the plurality of plug patterns 115 may be arranged in an array and distributed in the first memory area 11 and the second memory area 12. In a possible example, the forming, in a blank layout, a substrate pattern including a plurality of plug patterns spaced apart may include:

forming, in the blank layout, the substrate pattern including a plurality of active area sub patterns spaced apart and extending along the first direction.

Referring to FIG. 6 and FIG. 7, the plurality of active area sub patterns 111 extend along the first direction (the Z direction as shown in FIG. 5) and are arranged in parallel. Adjacent two of the plurality of active area sub patterns 111 are staggered in the third direction (the X direction as shown in FIG. 5), where the second direction intersects with the first direction. A plurality of word line patterns 113 spaced apart are also arranged in the substrate pattern. The plurality of word line patterns 113 extend in the third direction (the X direction as shown in FIG. 5) and are arranged in parallel in the second direction (the Y direction as shown in FIG. 5). The third direction intersects with the first direction, and the third direction also intersects with the second direction. Each of the plurality of word line patterns 113 intersects with some of the plurality of active area sub patterns 111 positioned in the same row and passes through these active area sub patterns 111, and each of the plurality of word line patterns 113 divides these active area sub patterns 111 into different areas. Exemplarily, number of word line patterns 113 intersecting with some of the plurality of active area sub patterns 111 in the same row is two, and the two word line patterns 113 separate these active area sub patterns 111 intersecting therewith into a first contact area 1111 positioned in middle and second contact areas 1112 positioned on two sides of the first contact area 1111.

After the substrate pattern is formed, a plurality of first data line patterns spaced apart and extending along the second direction are formed, where the second direction intersects with the first direction. Each of the plurality of first data line patterns shares a partially overlapped area with each of the plurality of active area sub patterns positioned in the same column.

Referring to FIG. 10 and FIG. 11, there are a plurality of first data line patterns 114, and the plurality of first data line patterns 114 are spaced apart and extend along the second direction (the Y direction as shown in FIG. 10), where the second direction intersects with the first direction. Each of the plurality of first data line patterns 114 shares a partially overlapped area with each of the plurality of active area sub patterns 111 positioned in the same column. Exemplarily, each of first data lines includes a plurality of conductive pillar sub patterns 1141 spaced apart and a plurality of conductive line sub patterns 1142 extending along the second direction. Each of the plurality of conductive pillar sub patterns 1141 shares a partially overlapped area with one of the plurality of active area sub patterns 111, and each of the plurality of conductive line sub patterns 1142 passes through some of the plurality of conductive pillar sub patterns 1141 positioned in the same column. Part of each of the plurality of conductive line sub patterns 1142 positioned in the first memory area 11 forms a source line pattern, and part of each of the plurality of conductive line sub patterns 1142 positioned in the second memory area 12 forms a bit line pattern.

After the plurality of first data line patterns are formed, a plurality of plug patterns positioned between adjacent two of the plurality of first data line patterns are formed, where each of the plurality of plug patterns shares a partially overlapped area with each of the plurality of active area sub patterns.

Referring to FIG. 14 and FIG. 15, the plurality of plug patterns 115 includes a plurality of first plug sub patterns 1151 and a plurality of second plug sub patterns 1152. The plurality of first plug sub patterns 1151 are spaced apart, and the plurality of first plug sub patterns 1151 may be arranged in a matrix array. The plurality of second plug sub patterns 1152 are spaced apart and are in one-to-one correspondence with the plurality of first plug sub patterns 1151. Each of the plurality of first plug sub patterns 1151 and each of the plurality of second plug sub pattern 1152 corresponding to each other share a partially overlapped area. The plurality of second plug patterns 115 may be arranged in a hexagonal close-packed structure.

Referring to FIG. 12 and FIG. 13, each of the plurality of first plug sub patterns 1151 is positioned between adjacent two of the plurality of first data line patterns 114 and shares a partially overlapped area with each of the plurality of active area sub patterns 111, and each of the plurality of second plug sub patterns 1152 shares a partially overlapped area with each of the plurality of first data line patterns 114 and each of the plurality of first plug sub patterns 1151, respectively. Each of the plurality of second plug sub patterns 1152 positioned in the first memory area 11 forms a first electrode contact pattern, and each of the plurality of the second plug sub patterns 1152 positioned in the second memory area 12 forms a landing pad pattern.

Step S200: forming a storage pattern including a magnetic tunnel junction pattern positioned in the first memory area and a capacitor pattern positioned in the second memory area, where the magnetic tunnel junction pattern shares a partially overlapped area with a given one of the plurality of plug patterns positioned in the first memory area, and the capacitor pattern shares a partially overlapped area with a given one of the plurality of plug patterns positioned in the second memory area.

In some possible examples, the forming a storage pattern may include:

forming an initial magnetic tunnel junction pattern covering the base substrate array pattern. Part of the base substrate array pattern is positioned in the first memory area, another part of the base substrate array pattern is positioned in the second memory area, and the initial magnetic tunnel junction pattern covers the entire base substrate array pattern. The initial magnetic tunnel junction pattern is an enclosed pattern, in which no opening or hole is provided.

After the initial magnetic tunnel junction pattern is formed, a first pattern is formed in the initial magnetic tunnel junction pattern positioned in the first memory area, such that the initial magnetic tunnel junction pattern having the first pattern forms a magnetic tunnel junction pattern. Referring to FIG. 2, the initial tunnel junction patterns in the first memory area 11 are processed to form a plurality of magnetic tunnel junction patterns 121, and the plurality of magnetic tunnel junction patterns 121 are spaced apart. The plurality of magnetic tunnel junction patterns 121 may be arranged in a hexagonal close-packed structure, and each of the plurality of magnetic tunnel junction patterns 121 shares a partially overlapped area with one of the plurality of plug patterns 115 in the base substrate array pattern in the first memory area 11.

After the plurality of magnetic tunnel junction patterns are formed, the initial magnetic tunnel junction patterns positioned in the second memory area are removed. Rest of the initial magnetic tunnel junction patterns are removed, the plurality of magnetic tunnel junction patterns are remain, and no other pattern is covered on the base substrate array pattern in the second memory area.

After removing the initial magnetic tunnel junction patterns in the second memory area, an initial capacitor pattern is formed, and the initial capacitor pattern covers the magnetic tunnel junction pattern in the first memory area and the base substrate array pattern in the second memory area. As an enclosed pattern in which no opening or hole is provided, the initial capacitor pattern covers the base substrate array pattern and the magnetic tunnel junction pattern.

After the initial capacitor pattern is formed, a second pattern is formed in the initial capacitor pattern positioned in the second memory area, such that the initial capacitor pattern having the second pattern forms a capacitor pattern. Referring to FIG. 3, the initial capacitor patterns positioned in the second memory area 12 are processed to form a plurality of capacitor patterns 116 positioned in the second memory area 12, and the plurality of capacitor patterns 116 are spaced apart. The plurality of capacitor patterns 116 are arranged in a hexagonal close-packed structure, and each of the plurality of capacitor patterns 116 shares a partially overlapped area with one of the plurality of plug patterns 115 in the base substrate array pattern in the second memory area 12.

After the plurality of capacitor patterns are formed, the initial capacitor patterns positioned in the first memory area are removed. Rest of the initial capacitor patterns are removed, the plurality of capacitor patterns 116 are retained, and no other pattern is covered on the magnetic tunnel junction patterns 121 in the first memory area 11.

To sum up, the layout in the embodiments of the present disclosure has a first memory area 11 and a second memory area 12 at least partially surrounding the first memory area 11. The method for processing a layout includes: forming, in a blank layout, a base substrate array pattern including a plurality of plug patterns 115 spaced apart; and forming a storage pattern, which includes a magnetic tunnel junction pattern 121 positioned in the first memory area 11 and a capacitor pattern 116 positioned in the second memory area 12. The magnetic tunnel junction pattern 121 shares a partially overlapped area with a given one of the plurality of plug patterns 115 positioned in the first memory area 11, and the capacitor pattern 116 shares a partially overlapped area with a given one of the plurality of plug patterns 115 positioned in the second memory area 12. The magnetic tunnel junction patterns 121 positioned in the first memory area 11 and the base substrate array pattern may be configured to form patterns of an MRAM, and the capacitor patterns 116 positioned in the second memory area 12 and the base substrate array pattern may be configured to form patterns of a DRAM, such that the layout formed includes both the patterns of the DRAM and the patterns of the MRAM. When the layout is used for production subsequently, the MRAM may be fabricated by means of a fabrication process of the DRAM, such that a memory density of the MRAM is improved, and thus the integration of the MRAM is further improved, and the integration of the semiconductor device is improved.

In a possible example of the present disclosure, after forming a storage pattern (Step S200), the method further includes:

Step S300: forming an initial conductive pattern covering the magnetic tunnel junction patterns in the first memory area and the capacitor patterns in the second memory area. As an enclosed pattern in which no opening or hole is provided, the initial conductive pattern covers each of the magnetic tunnel junction patterns and each of the capacitor patterns.

Step S400: removing the initial conductive patterns positioned in the first memory area, the initial conductive patterns retained forming conductive patterns. The initial conductive patterns in the first memory area are removed, and the initial conductive patterns in the second memory area are retained. Referring to FIG. 16, each of the initial conductive patterns retained forms a conductive pattern 117 covering each of the plurality of capacitor patterns 116, and no other pattern is covered on the magnetic tunnel junction patterns 121 in the first memory area 11.

Step S500: forming an initial second electrode contact pattern covering each of the magnetic tunnel junction patterns in the first memory area and each of the conductive patterns in the second memory area. As an enclosed pattern in which no opening or hole is provided, the initial second electrode contact pattern covers each of the magnetic tunnel junction patterns and each of the conductive patterns.

Step S600: forming a third pattern in the initial second electrode contact pattern positioned in the first memory area, such that the initial second electrode contact pattern having the third pattern forms each of the plurality of second electrode contact patterns. Referring to FIG. 17, the initial second electrode contact patterns positioned in the first memory area 11 are processed to form a plurality of second electrode contact patterns 122 spaced apart, where each of the plurality of second electrode contact patterns 122 is overlapped with at least a partial area of one of the plurality of magnetic tunnel junction patterns 121. Exemplarily, the plurality of second electrode contact patterns 122 may be arranged in a rectangular array.

Step S700: removing the initial second electrode contact patterns positioned in the second memory area. Rest of the initial second electrode contact patterns are removed, the plurality of second electrode contact patterns are retained, and no other pattern is covered on the conductive patterns in the second memory area.

In a possible example, as shown in FIG. 17 and FIG. 18, the plurality of second electrode contact patterns 122 are arranged in a rectangular array. After removing the initial second electrode contact patterns 122 positioned in the second memory area 12, the method further include: forming a plurality of second data line patterns 123 spaced apart and extending along the second direction, where each of the plurality of second data line patterns 123 shares a partially overlapped area with each of the plurality of second electrode contact patterns 122 and passes through some of the plurality of second electrode contact patterns 122 positioned in the same column.

The embodiments of the present disclosure further provides a storage medium storing computer-executable instructions, and the computer-executable instructions are executable by a processor, whereby the method for processing a layout in any one of the foregoing embodiments of the present disclosure is implemented. The storage medium may be a medium which can store instructions executable by a computer, such as a U disk, a mobile hard disk, a readable memory, a magnetic disk or an optical disk, etc. The storage medium in the embodiments of the present disclosure is configured to implement the above processing method, and thus at least has the advantages of the above method for processing a layout. Reference may be made to the above for concrete effects of the storage medium, and detailed descriptions thereof are omitted here.

The embodiments of the present disclosure further provide a program product including a computer program; the computer program is executable by a processor, whereby the method for processing a layout in any one of the foregoing embodiments of the present disclosure is implemented. The program product in the embodiments of the present disclosure is configured to implement the above method for processing a layout, and thus at least has the advantages of the above method for processing a layout. Reference may be made to the above for concrete effects of the program product, and detailed descriptions thereof are omitted here.

In the above embodiments, the method for processing a layout may be implemented in whole or in part by software, hardware, firmware or any combination thereof. When implemented in software, the method for processing a layout may be implemented, partly or entirely, in the form of a computer program product. The computer program product of the present disclosure includes one or more computer instructions. When the one or more computer program instructions of the present disclosure are loaded and executed on a computer, the flows or functions according to the embodiments of the present disclosure may be generated, partly or entirely. The computer of the present disclosure may be a general purpose computer, a special purpose computer, a computer network, or other programmable devices. The computer instructions of the present disclosure may be stored in a computer-readable storage medium or transferred from one computer-readable storage medium to another computer-readable storage medium. For example, the computer instructions of the present disclosure may be transferred from a website, a computer, a server or a data center to another website, computer, server, or data center by wire (e.g., coaxial cable, fiber optic, digital subscriber line (DSL)) or wirelessly (e.g., infrared, wireless, microwave, etc.). The computer-readable storage medium of the present disclosure may be any available medium that can be accessed by a computer or a data storage device that includes one or more available media integrated server, data center, or the like. The medium available in the present disclosure may be magnetic medium (e.g., floppy disk, hard disk, magnetic tape), optical medium (e.g., DVD), or semiconductor medium (e.g., solid state disk (SSD)), and the like.

The embodiments or the implementation manners in this specification are described in a progressive manner. Each of the embodiments is focused on difference from other embodiments, and cross reference is available for identical or similar parts among different embodiments.

In the descriptions of this specification, descriptions of reference terms “one embodiment”, “some embodiments”, “an exemplary embodiment”, “an example”, “one example”, or “some examples” are intended to indicate that features, structures, materials, or characteristics described with reference to the embodiments or example are included in at least one embodiment or example of the present disclosure. The schematic representation of the above terms throughout this specification does not necessarily refer to the same embodiment or example. Furthermore, the features, structures, materials, or characteristics set forth may be combined in any suitable manner in one or more embodiments or examples.

Finally, it should be noted that the foregoing embodiments are merely intended for describing the technical solutions of the present disclosure, but not for limiting the present disclosure. Although the present disclosure is described in detail with reference to the foregoing embodiments, persons of ordinary skill in the art should understand that they may still make modifications to the technical solutions described in the foregoing embodiments or make equivalent replacements to some or all technical features thereof, which does not make corresponding technical solutions in essence depart from the scope of the technical solutions of the embodiments of the present disclosure.

What is claimed is:

1. A layout having a first memory area and a second memory area at least partially surrounding the first memory area, the layout comprising:
a base substrate array pattern comprising a plurality of plug patterns spaced apart; and
a storage pattern comprising a magnetic tunnel junction pattern positioned in the first memory area and a capacitor pattern positioned in the second memory area, the magnetic tunnel junction pattern sharing a partially overlapped area with a given one of the plurality of plug patterns positioned in the first memory area, and the capacitor pattern sharing a partially overlapped area with a given one of the plurality of plug patterns positioned in the second memory area.

2. The layout according to claim 1, wherein the base substrate array pattern comprises:
a substrate pattern comprising a plurality of active area sub patterns spaced apart, the plurality of active area sub patterns extending along a first direction; and
a plurality of first data line patterns spaced apart and extending along a second direction, the second direction intersecting with the first direction, and each of the plurality of first data line patterns and a given one of the plurality of active area sub patterns positioned in a same column sharing a partially overlapped area;
wherein the plurality of plug patterns are positioned between adjacent two of the plurality of first data line patterns and share partially overlapped areas with the plurality of active area sub patterns.

3. The layout according to claim 2, wherein each of the plurality of first data line patterns comprises a plurality of conductive pillar sub patterns spaced apart and a plurality of conductive line sub patterns extending along the first direction; and
each of the plurality of conductive pillar sub patterns shares a partially overlapped area with a given one of the plurality of active area sub patterns, each of the plurality of conductive line sub patterns passing through some of the plurality of conductive pillar sub patterns positioned in the same column; and part of each of the plurality of conductive line sub patterns positioned in the first memory area forms a source line pattern, part of each of the plurality of conductive line sub patterns positioned in the second memory area forming a bit line pattern.

4. The layout according to claim 3, wherein a plurality of word line patterns spaced apart and extending along a third direction are further provided in the substrate pattern, the third direction intersecting with the first direction, the third direction intersecting with the second direction; and
each of the plurality of word line patterns intersects with and passes through the plurality of active area sub patterns in a same row.

5. The layout according to claim 4, wherein for a same one of the plurality of word line patterns, a second insulation pattern is further provided between part of the same word line pattern positioned in the first memory area and part of the same word line pattern positioned in the second memory area.

6. The layout according to claim 4, wherein number of the plurality of word line patterns intersecting with the plurality of active area sub patterns in the same row is two, the two word line patterns dividing each of the plurality of active area sub patterns intersecting therewith into a first contact area positioned in a middle, and a second contact area positioned on two sides of the first contact area; and
each of the plurality of conductive pillar sub patterns overlaps with a partial area of the first contact area, each of the plurality of plug patterns overlapping with a partial area of the second contact area.

7. The layout according to claim 2, wherein the plurality of plug patterns comprises a first plug sub pattern and a second plug sub pattern corresponding to the first plug sub pattern;
the first plug sub pattern is positioned between adjacent two of the plurality of first data line patterns, the second plug sub pattern sharing a partially overlapped area with each of the plurality of first data line patterns and the first plug sub pattern; and
the second plug sub pattern positioned in the first memory area forms a first electrode contact pattern, the second plug sub pattern positioned in the second memory area forming a landing pad pattern.

8. The layout according to claim 7, wherein each of the plurality of capacitor patterns shares a partially overlapped area with one of the landing pad patterns, the plurality of capacitor patterns being arranged in a hexagonal close-packed structure.

9. The layout according to claim 8, wherein the layout further comprises a conductive pattern positioned in the second memory area, the conductive pattern covering each of the plurality of capacitor patterns.

10. The layout according to claim 8, wherein the layout further comprises a plurality of second electrode contact patterns, each of the plurality of second electrode contact patterns being overlapped with at least a partial area of one of the magnetic tunnel junction patterns.

11. The layout according to claim 10, wherein the magnetic tunnel junction patterns are arranged in a hexagonal close-packed structure, the plurality of second electrode contact patterns being arranged in a rectangular array.

12. The layout according to claim 10, wherein the layout further comprises a plurality of second data line patterns spaced apart and extending along the second direction, each of the plurality of second data line patterns sharing a partially overlapped area with each of the plurality of second electrode contact patterns and passing through the plurality of second electrode contact patterns positioned in a same column.

13. A method for processing a layout, the layout having a first memory area and a second memory area at least partially surrounding the first memory area;
wherein the processing method comprises:
forming, in a blank layout, a base substrate array pattern comprising a plurality of plug patterns spaced apart; and
forming a storage pattern, the storage pattern comprising a magnetic tunnel junction pattern positioned in the first memory area and a capacitor pattern positioned in the second memory area, the magnetic tunnel junction pattern sharing a partially overlapped area with a given one of the plurality of plug patterns positioned in the first memory area, and the capacitor pattern sharing a partially overlapped area with a given one of the plurality of plug patterns positioned in the second memory area.

14. The processing method according to claim 13, wherein the forming, in a blank layout, a base substrate array pattern comprising a plurality of plug patterns spaced apart comprises:
forming, in the blank layout, a substrate pattern comprising a plurality of active area sub patterns spaced apart, the plurality of active area sub patterns extending along a first direction;
forming a plurality of first data line patterns spaced apart and extending along a second direction, the second direction intersecting with the first direction; each of the plurality of first data line patterns sharing a partially overlapped area with each of the plurality of active area sub patterns positioned in a same column; and
forming a plurality of plug patterns positioned between adjacent two of the plurality of first data line patterns, each of the plurality of plug patterns sharing a partially overlapped area with each of the plurality of active area sub patterns.

15. The processing method according to claim 13, wherein the forming a storage pattern comprises:
forming an initial magnetic tunnel junction pattern covering the base substrate array pattern;
forming a first pattern in the initial magnetic tunnel junction pattern positioned in the first memory area, such that the initial magnetic tunnel junction pattern having the first pattern forms the magnetic tunnel junction pattern;
removing the initial magnetic tunnel junction pattern positioned in the second memory area;
forming an initial capacitor pattern covering the magnetic tunnel junction pattern in the first memory area and the base substrate array pattern in the second memory area;
forming a second pattern in the initial capacitor pattern positioned in the second memory area, such that the initial capacitor pattern having the second pattern forms the capacitor pattern; and
removing the initial capacitor pattern positioned in the first memory area.

16. The processing method according to claim 13, wherein after forming the storage pattern, the processing method further comprises:
forming an initial conductive pattern covering the magnetic tunnel junction pattern in the first memory area and the capacitor pattern in the second memory area; and
removing the initial conductive pattern positioned in the first memory area such that the initial conductive pattern retained forms a conductive pattern.

17. The processing method according to claim 16, wherein after the removing the initial conductive pattern positioned in the first memory area such that the initial conductive pattern retained forms a conductive pattern, the processing method further comprises:
forming an initial second electrode contact pattern covering the magnetic tunnel junction pattern in the first memory area and the conductive pattern in the second memory area;
forming a third pattern in the initial second electrode contact pattern positioned in the first memory area, such that the initial second electrode contact pattern having the third pattern forms the plurality of second electrode contact patterns; and
removing the initial second electrode contact pattern positioned in the second memory area.

18. The processing method according to claim 17, wherein the plurality of second electrode contact patterns are arranged in a rectangular array;
after the removing the initial second electrode contact pattern positioned in the second memory area, the processing method further comprises:
forming a plurality of second data line patterns spaced apart and extending along the second direction, each of the plurality of second data line patterns sharing a partially overlapped area with each of the plurality of second electrode contact patterns and passing through the plurality of second electrode contact patterns positioned in a same column.

19. A non-transitory storage medium storing computer-executable instructions, wherein the computer-executable instructions are executable by a processor to implement a method for processing a layout, the layout having a first memory area and a second memory area at least partially surrounding the first memory area;
wherein the processing method comprises:
forming, in a blank layout, a base substrate array pattern comprising a plurality of plug patterns spaced apart; and
forming a storage pattern, the storage pattern comprising a magnetic tunnel junction pattern positioned in the first memory area and a capacitor pattern positioned in the second memory area, the magnetic tunnel junction pattern sharing a partially overlapped area with a given one of the plurality of plug patterns positioned in the first memory area, and the capacitor pattern sharing a partially overlapped area with a given one of the plurality of plug patterns positioned in the second memory area.

20. A program product comprising a computer program, wherein the computer program is executable by a processor to implement a method according to claim 13.
